(19) United States
(12) Patent Application Publication
(10) Pub. No.: US 2008/0150166 A1
(43) Pub. Date: Jun. 26, 2008

(54) METHOD FOR FORMING METAL WIRING IN SEMICONDUCTOR DEVICE

(76) Inventor: Seung-Hyun Kim, Seoul (KR)

Correspondence Address: SHERR & NOURSE, PLLC, 620 HERNDON PARKWAY, SUITE 200, HERNDON, VA, 20170, US

(21) Appl. No.: 11/958,035

(22) Filed: Dec. 17, 2007

(30) Foreign Application Priority Data
Dec. 26, 2006 (KR) 10-2006-0133387

(51) Int. Cl. H01L 23/52; B32B 15/00; H01L 21/3205; B32B 3/10

(52) U.S. Cl. 257/784; 428/457; 428/137; 438/659; 257/E21.575; 257/E23.141

(57) ABSTRACT

Embodiments relate to a metal wiring in a semiconductor device that may be formed by depositing a metal layer on a semiconductor substrate, and performing ion bombardment on a surface of the metal layer to thereby forming the metal wiring. According to embodiments, the metal layer may be etched and ion bombardment may then be performed on the surface of the metal wiring to form the metal wiring.

The present application claims priority under 35 U.S.C. 119 and 35 U.S.C. 365 to Korean Patent Application No. 10-2006-0133387 (filed on Dec. 26, 2006), which is hereby incorporated by reference in its entirety.

### BACKGROUND

As the degree of integration of semiconductor devices increases, the design rule may significantly reduce and a metal wiring for electrical connection of circuits may become multi-layered and smaller. As such high integration becomes more prevalent, the number of metal wirings may significantly increase and the pitch of the metal wiring may greatly decrease. This may result in increased line resistance and a long RC time due to increased parasitic capacitance between neighboring wirings. Accordingly, the speed of the semiconductor device may be reduced.

Aluminum (Al) or copper (Cu) with a good conductivity may be used as a material for metal wirings. However, it may be difficult to apply dry etch to copper (Cu) wiring. Hence, a dual damascene process may be applied to copper (Cu) wiring. Thus, the copper (Cu) wiring may be problematic in that it may have a process cost higher than that of the aluminum (Al) wiring.

FIG. 1 is a cross-sectional drawing illustrating a related art method of forming a metal wiring in a semiconductor device.

Referring to FIG. 1a, pre-metal dielectric layer 110 may be formed on semiconductor substrate 100 having an underlying structure including a lower metal wiring (not shown). Pre-metal dielectric layer 110 may be selectively etched to form via hole 120, which may penetrate in upward and downward directions and have an opening. Metal, having a good gap-fill characteristic while having the conductivity, may be filled within corresponding via hole 120, and may form plug 130, which may electrically connect the lower metal wiring and upper metal wiring 140′ to be formed later.

Pre-metal dielectric layer 110 may be generally formed from an oxide layer, and plug 130 may be generally formed from tungsten (W) material.

Referring to FIG. 1b, upper metal layer 140, for example made of aluminum (Al), etc. may be deposited on the entire surface, including plug 130, to a specific thickness in order to form the upper metal wiring.

Referring to FIG. 1c, a photoresist PR may be coated on upper metal layer 140. A photolithography process using exposure and development may be performed on the photoresist PR to form photoresist pattern 150.

Referring to FIG. 1d, exposed portions of upper metal layer 140 may be selectively etched and removed by using corresponding photoresist pattern 150 as a mask, /so that upper metal wiring 140′ may be formed.

Referring to FIG. 1e, photoresist pattern 150 may be removed by an ashing process.

In addition, an adhesion-improved glue layer, a barrier layer, an anti-reflective coating layer and so on may be formed between pre-metal dielectric layer 110 and lower and upper metal wiring 140′.

In the related art, however, as described above, as the degree of integration of semiconductor devices increases, line resistance may greatly increase. Thus, it may be necessary to effectively lower such line resistance. However, to lower the line resistance, there may be no other alternative method except for increasing the area by increasing the thickness or line width of metal wiring 140′. This method of increasing the area cannot be adopted because it is contrary to high integration.

### SUMMARY

Embodiments relate, in general, to a method of forming a metal wiring in a semiconductor device and, more particularly, to a method of forming a metal wiring in a semiconductor device, in which ion bombardment may be performed on a surface of the metal wiring in order to form a large quantity of grain boundaries, which may become a major current path, within the surface. This may reduce line resistance.

Embodiments relate to a method of forming a metal wiring of a semiconductor device in which as current may flow primarily through a surface side of a metal wiring. Ion bombardment may be performed on the surface of the metal wiring, which may be formed to reduce line resistance by allowing the current to flow well on the surface side, thus forming a large quantity of grain boundaries, which become a major current path, within the surface.

According to embodiments, a method of forming a metal wiring in a semiconductor device may include depositing a metal layer on a semiconductor substrate, and performing ion bombardment on a surface of the metal layer to thereby form the metal wiring.

According to embodiments, a method of forming a metal wiring in a semiconductor device may include depositing a metal layer on a semiconductor substrate, etching the metal layer to form an etched metal wiring, and performing ion bombardment on the surface of the etched metal wiring to thereby form the metal wiring.

### DRAWINGS

FIG. 1 is a cross-sectional drawing illustrating a related art method of forming a metal wiring for a semiconductor device; and

FIG. 2 is a cross-sectional drawing illustrating a method of forming a metal wiring of a semiconductor device in accordance with embodiments.

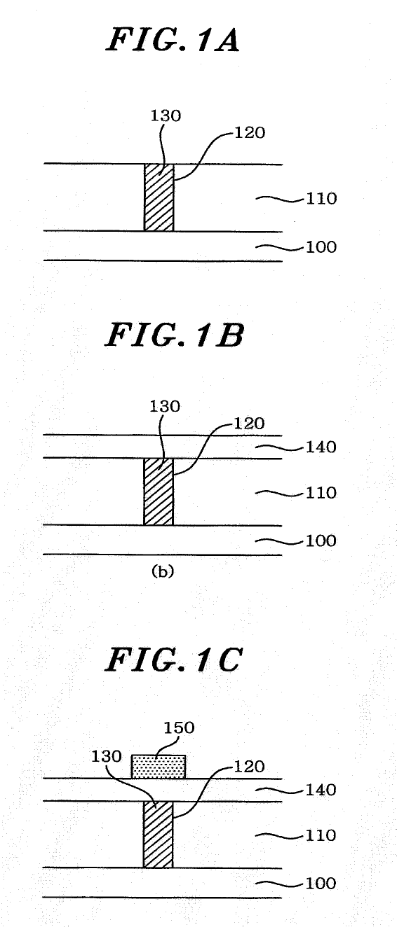

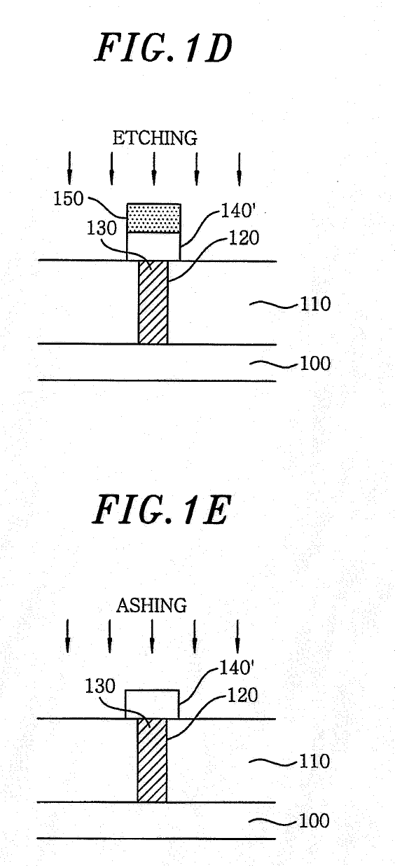

### DESCRIPTION

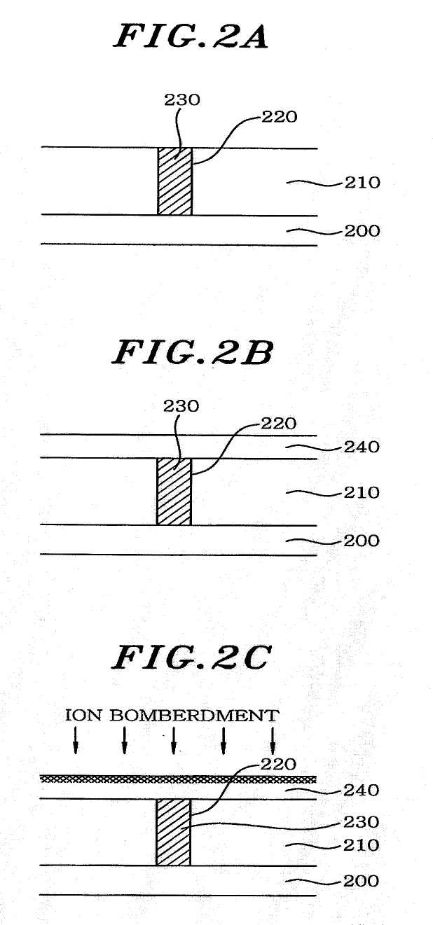

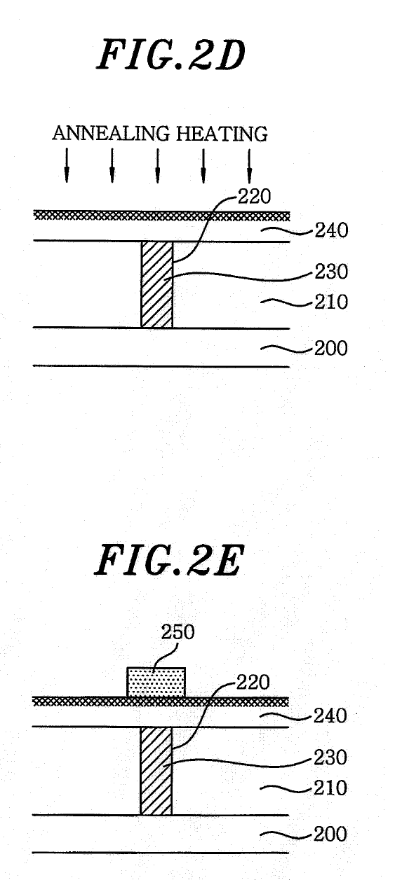

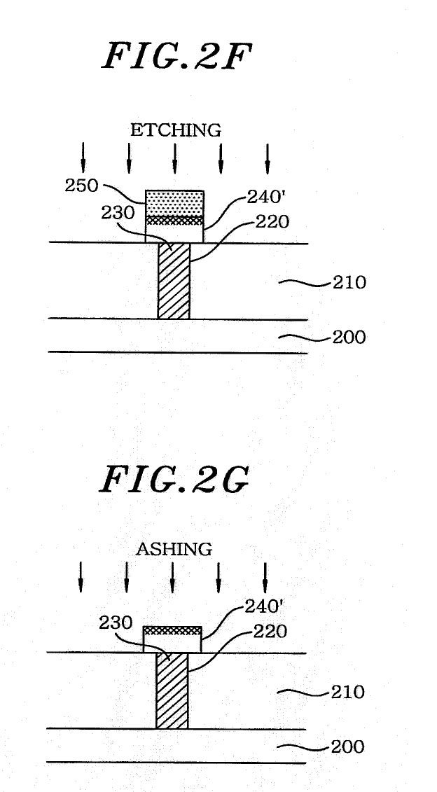

Referring to FIG. 2a, pre-metal dielectric layer 210 may be formed on semiconductor substrate 200, which may have an underlying structure including a lower metal wiring (not shown). Pre-metal dielectric layer 210 may be selectively etched to form via hole 220. Metal may be deposited within corresponding via hole 220 and may form plug 230.

Referring to FIG. 2b, upper metal layer 240, which may be made of aluminum (Al) or the like, may be deposited on a surface, for example, the entire surface, including plug 230, and may form upper metal wiring 240′.

Referring to FIG. 2c, ion bombardment using a neutral gas as a process gas may be performed on the surface of upper metal layer 240. In embodiments, this process may be performed in such a manner that ions strongly bombard the surface of upper metal layer 240. Thus, as particles on a corresponding surface are broken, they may generate a large quantity of grain boundaries between corresponding particles.

Referring to FIG. 2d, an annealing process may be performed and may realign the particles shocked by ion bombardment and adjust the particle size of micro particles.

Referring to FIG. 2e, photoresist pattern 250 may be formed on upper metal layer 240 through a photolithography process.

Referring to FIG. 2f, exposed upper metal layer 240 may be selectively etched and removed by using a corresponding photoresist pattern 250 as a mask, and upper metal wiring 240′ may be formed.

Referring to FIG. 2f, photoresist pattern 250 may be removed, for example by an ashing process.

As described above, according to embodiments, after metal layer 240 for forming a metal wiring, ion bombardment may be performed on the surface of corresponding metal layer 240. Ion bombardment may be performed using a neutral gas, such as Ar, N₂ or He, as a process gas through plasma equipment.

In embodiments, neutral gas may be used as the process gas may because ions formed from a corresponding gas may be simply used to give shock to the surface of metal layer 240, but may not have an effect on the characteristics of metal layer 240.

According to embodiments, a method of implementing ion bombardment using the plasma equipment is briefly described below. Semiconductor substrate 200 having metal layer 240 formed thereon may be loaded within a process chamber. Power may be applied to form plasma within the process chamber. A process gas may be then introduced into the chamber, decomposed by plasma and then ionized. The ionized ions may be accelerated and may collide against a surface of semiconductor substrate 200.

According to embodiments, particles within the surface of metal layer 240 may be finely broken through ion bombardment and grain boundaries may be generated in great quantities. If the grain boundaries are increased as described above, when current is applied to metal wiring 240′, it can easily flow through the surface side of metal wiring 240′ through the large quantity of grain boundaries. Accordingly, line resistance may be reduced significantly.

Ion bombardment may be used to increase grain boundaries, which may become a major passage through which current flows. In embodiments, it may lead to decreased particle size, i.e., a reduced grain size.

Consequently, according to embodiments, line resistance may be reduced while not increasing a thickness or line width of metal wiring 240′. Embodiments may promote high integration of semiconductor devices and may also improve characteristics.

Further, in the related art, an electromigration (EM) phenomenon, in which the atoms of a region within metal wiring 240′ may all move to other places, may occur and an empty region may have been formed. This may cause degradation of device characteristics. According to embodiments, however, if grain boundaries are formed in great quantities within the surface side as in the present invention, an electromigration (EM) phenomenon of metal atoms may be reduced or prevented.

According to embodiments, ion bombardment may be performed on upper metal wiring 240′. In embodiments, such ion bombardment may also be performed on all metal wirings including the lower metal wiring.

According to embodiments, after the metal layer 240 is formed, ion bombardment and annealing may be carried out before photoresist pattern 250 may be formed. However, in embodiments, after the metal wiring 240′ is formed, ion bombardment and annealing may be performed on the surface of corresponding metal wiring 240′.

In embodiments, annealing may be performed after ion bombardment. In embodiments, annealing may be not required, but instead may be optional.

In accordance with embodiments, ion bombardment may be performed on a surface of a metal wiring and grain boundaries, which become a major current passage, may be created in great quantities within the surface. This may reduce line resistance. Accordingly, it may be not necessary to increase the thickness or line width of the metal wiring so as to reduce line resistance. It may be very advantageous in terms of high integration of semiconductor devices. The characteristics of semiconductor devices may also be accomplished through a significant reduction in line resistance.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A method, comprising:
depositing a metal layer over a semiconductor substrate; and
performing ion bombardment on a surface of the metal layer to form a metal wiring.

2. The method of claim 1, further comprising performing annealing after performing the ion bombardment.

3. The method of claim 1, wherein a neutral gas is used to perform the ion bombardment.

4. The method of claim 1, wherein the ion bombardment is performed by using a plasma equipment.

5. A method, comprising:
depositing a metal layer over a semiconductor substrate;
etching the metal layer to form an etched metal wiring; and
performing ion bombardment on a surface of the etched metal wiring to form a metal wiring.

6. The method of claim 5, further comprising performing annealing after performing the ion bombardment.

7. The method of claim 5, wherein a neutral gas is used as a process gas to perform the ion bombardment.

8. The method of claim 5, wherein the ion bombardment is performed by using plasma equipment.

9. A device, comprising:
a semiconductor substrate; and
a metal wiring over the semiconductor substrate, wherein the metal wiring is formed by bombarding an etched metal wiring over the semiconductor substrate with ions.

10. The device of claim 9, wherein the metal wiring is annealed after the ion bombardment.

11. The device of claim 9, wherein the ion bombardment is achieved using a neutral gas to perform the ion bombardment.

12. The device of claim 9, wherein the ion bombardment is performed using plasma equipment.

13. The device of claim 9, wherein the etched metal wiring is formed by depositing a metal layer over the semiconductor substrate and etching the metal layer to form an etched metal wiring.

14. The device of claim 9, further comprising a via hole to couple the metal wiring to the semiconductor substrate.
